(19) United States
(12) Patent Application Publication
(10) Pub. No.: US 2026/0293434 A1
(43) Pub. Date: Sep. 24, 2026

(54) DISPLAY DEVICE, ELECTRONIC DEVICE INCLUDING THE SAME, AND METHOD OF MANUFACTURING THE DISPLAY DEVICE

(71) Applicant: Samsung Display Co., Ltd., Yongin-Si (KR)

(72) Inventors: Yunhee Park, Yongin-si (KR); Kyeongjong Kim, Yongin-si (KR); Sujeong Kim, Yongin-si (KR); Yiseop Shim, Yongin-si (KR); Hyunseung Lee, Yongin-si (KR); Kyuwon Cho, Yongin-si (KR)

(21) Appl. No.: 19/410,045

(22) Filed: Dec. 5, 2025

(30) Foreign Application Priority Data
Mar. 21, 2025 (KR) 10-2025-0036621

(51) Int. Cl. H10K 50/86; H10K 59/12; H10K 59/122; H10K 59/35; H10K 59/38

(52) U.S. Cl. CPC H10K 50/865; H10K 59/1201; H10K 59/122; H10K 59/38; H10K 59/35

(57) ABSTRACT

A display device includes a substrate, a display layer disposed on the substrate and including a first light-emitting diode and a bank layer that includes a first lower opening defining an emission area of the first light-emitting diode, and an optical control layer disposed on the display layer and including a light-shielding layer that includes a first upper opening at least partially aligned with the first lower opening and a first color filter filling the first upper opening, wherein the first color filter passes light of a first color among light emitted from the first light-emitting diode, the first color filter includes a plurality of first scattering particles and a base resin, and the plurality of first scattering particles are disposed in an upper area of the first color filter.

### CROSS-REFERENCE TO RELATED APPLICATION

This application is based on and claims priority under 35 U.S.C. § 119 to Korean Patent Application No. 10-2025-0036621, filed on Mar. 21, 2025, in the Korean Intellectual Property Office, the disclosure of which is incorporated by reference herein in its entirety.

### BACKGROUND

### 1. Field

One or more embodiments relate to a display device, an electronic device including the same, and a method of manufacturing the display device.

### 2. Description of the Related Art

Display devices visually display data. Display devices may be used as displays of small-sized products such as mobile phones or large products such as televisions.

A display device includes a plurality of pixels emitting light by receiving electrical signals to externally display images. Each pixel includes a display element. For example, an organic light-emitting display device includes an organic light-emitting diode (OLED) as a display element.

Recently, as the purpose of use of display devices has diversified, various attempts have been made to design display devices with improved quality.

### SUMMARY

One or more embodiments include a display device with improved display quality, an electronic device including the display device, and a method of manufacturing the display device. However, such a technical problem is just an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display device includes a substrate, a display layer disposed on the substrate and including a first light-emitting diode and a bank layer that includes a first lower opening defining an emission area of the first light-emitting diode, and an optical control layer disposed on the display layer and the optical control layer including a light-shielding layer that includes a first upper opening at least partially aligned with the first lower opening, and a first color filter filling the first upper opening, wherein the first color filter passes light of a first color among light emitted from the first light-emitting diode, the first color filter includes a plurality of first scattering particles and a base resin, and the plurality of first scattering particles are disposed in an upper area of the first color filter.

According to one or more embodiments, an upper surface of the first color filter may include a plurality of convex portions protruding by the plurality of first scattering particles.

According to one or more embodiments, the first color filter may have a non-uniformly curved upper surface.

According to one or more embodiments, the plurality of first scattering particles may surface-treated to be hydrophobic or liquid repellent.

According to one or more embodiments, the plurality of first scattering particles may include silica particles.

According to one or more embodiments, a content ratio of the plurality of first scattering particles in the first color filter may be 0.01% to 5%.

According to one or more embodiments, a radius of each of the plurality of first scattering particles may be 50 nm to 200 nm.

According to one or more embodiments, the display layer may further include a second light-emitting diode and a third light-emitting diode, wherein the second light-emitting diode and the third light-emitting diode may be spaced apart from the first light-emitting diode, the bank layer may further include a second lower opening defining an emission area of the second light-emitting diode and a third lower opening defining an emission area of the third light-emitting diode, the light-shielding layer may further include a second upper opening at least partially aligned with the second lower opening and a third upper opening at least partially aligned with the third lower opening, and the optical control layer may further include a second color filter filling the second upper opening and a third color filter filling the third upper opening, and the second color filter may pass light of a second color among light emitted from the second light-emitting diode, and the third color filter may pass light of a third color among light emitted from the third light-emitting diode.

According to one or more embodiments, the second color filter may include a plurality of second scattering particles, the third color filter may include a plurality of third scattering particles, and, at least one of plurality of scattering particles selected from the plurality of first scattering particles, the plurality of second scattering particles, and the plurality of third scattering particles may have a diameter different from others.

According to one or more embodiments, the display layer may further include a fourth light-emitting diode spaced apart from the first light-emitting diode, the bank layer may further include a fourth lower opening defining an emission area of the fourth light-emitting diode, the light-shielding layer may further include a fourth upper opening at least partially aligned the fourth lower opening, and the optical control layer may further include a fourth color filter filling the fourth upper opening, and wherein the fourth color filter and the first color filter may include a same material.

According to one or more embodiments, each of the first upper opening and the fourth upper opening may have an elliptical shape in a plan view, and an angle of an axis of the elliptical shape of the first upper opening may be different from an angle of an axis of the elliptical shape of the fourth upper opening.

According to one or more embodiments, a vertical distance between the substrate and a pixel electrode of the first light-emitting diode may be different from a vertical distance between the substrate and a pixel electrode of the fourth light-emitting diode.

According to one or more embodiments, the display device may further include a touch sensor layer disposed between the display layer and the optical control layer and including a touch electrode and a touch insulating layer covering the touch electrode, wherein the touch sensor layer may further include a reflective pattern disposed on a same layer as the touch electrode and overlapping the emission area, the optical control layer may further include a light-shielding pattern disposed on a same layer as the light-shielding layer and disposed in the first upper opening, and the light-shielding pattern may be arranged to overlap the reflective pattern in a plan view.

According to one or more embodiments, a method of manufacturing a display device includes forming, on a substrate, a display layer including a light-emitting diode and a bank layer that includes a lower opening defining an emission area of the light-emitting diode, forming, on the display layer, a light-shielding layer including an upper opening at least partially aligned with the lower opening, forming, within the upper opening, a preliminary color filter layer including a color filter material, a plurality of scattering particles, and a base resin, and forming a color filter layer through a pre-baking process of heating the preliminary color filter layer.

According to one or more embodiments, the plurality of scattering particles dispersed in the preliminary color filter layer may move to an upper portion of the color filter layer through the pre-baking process.

According to one or more embodiments, an upper surface of the color filter layer may include a plurality of convex portions protruding by the plurality of scattering particles.

According to one or more embodiments, the forming of the preliminary color filter layer may include forming the plurality of scattering particles by performing hydrophobic surface-treatment on silica particles.

According to one or more embodiments, an electronic device includes a display device configured to provide an image, a housing accommodating the display device, wherein the display device may include a substrate;
a display layer disposed on the substrate and including a light-emitting diode and a bank layer that includes a lower opening defining an emission area of the light-emitting diode; and an optical control layer disposed on the display layer and including a light-shielding layer that includes an upper opening at least partially aligned with the lower opening, and a color filter filling the upper opening; wherein the color filter may include a color filter material, a plurality of scattering particles, and a base resin, and the plurality of scattering particles may be disposed in an upper area of the color filter.

According to one or more embodiments, an upper surface of the color filter may include a plurality of convex portions protruding by the plurality of scattering particles.

According to one or more embodiments, the plurality of scattering particles may include hydrophobic surface-treated silica particles.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display device according to an embodiment.

FIG. 2 is an equivalent circuit diagram illustrating a light-emitting diode included in any one of sub-pixels of a display device and a sub-pixel circuit connected to the light-emitting diode, according to an embodiment.

FIG. 3 is a schematic cross-sectional view of the display device according to an embodiment, taken along a line I-I′ of FIG. 1.

FIG. 4 is a schematic plan view of a portion of a display device according to an embodiment.

FIG. 5 is a schematic cross-sectional view of a portion of a display device according to an embodiment.

FIG. 6 is an enlarged schematic cross-sectional view of a region VI of the display device of FIG. 5, according to an embodiment.

FIG. 7A is a graph illustrating scattering characteristics according to a measurement angle of light emitted from an organic light-emitting diode included in a display device according to an embodiment.

FIG. 7B is a graph illustrating scattering characteristics according to a measurement angle of light emitted from an organic light-emitting diode included in a display device according to an embodiment.

FIG. 7C is a graph illustrating scattering characteristics according to a measurement angle of light emitted from an organic light-emitting diode included in a display device according to an embodiment.

FIG. 8A is a schematic cross-sectional view illustrating a method of manufacturing a display device, according to an embodiment.

FIG. 8B is a schematic cross-sectional view illustrating a method of manufacturing a display device, according to an embodiment.

FIG. 8C is a schematic cross-sectional view illustrating a method of manufacturing a display device, according to an embodiment.

FIG. 8D is a schematic cross-sectional view illustrating a method of manufacturing a display device, according to an embodiment.

FIG. 9A is a schematic plan view of a portion of a display device according to an embodiment.

FIG. 9B is a schematic cross-sectional view of a portion of a display device according to an embodiment.

FIG. 10 is a schematic cross-sectional view of a portion of a display device according to an embodiment.

FIG. 11 is a block diagram of an electronic device according to an embodiment.

FIG. 12 is a schematic diagram of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving the same will be clarified with reference to embodiments described below in detail with reference to the drawings. However, the disclosure is not limited to the following embodiments and may be embodied in various forms.

Hereinafter, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

In the case where a certain embodiment may be implemented differently, a specific process order may be performed in an order different from the described order. For example, two processes successively described may be simultaneously performed substantially or performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

An x-axis, a y-axis and a z-axis are not limited to three axes of a rectangular coordinate system, and may be interpreted in a broader sense. For example, the x-axis, the y-axis, and the z-axis may be perpendicular to one another, or may represent different orientations that are not perpendicular to one another.

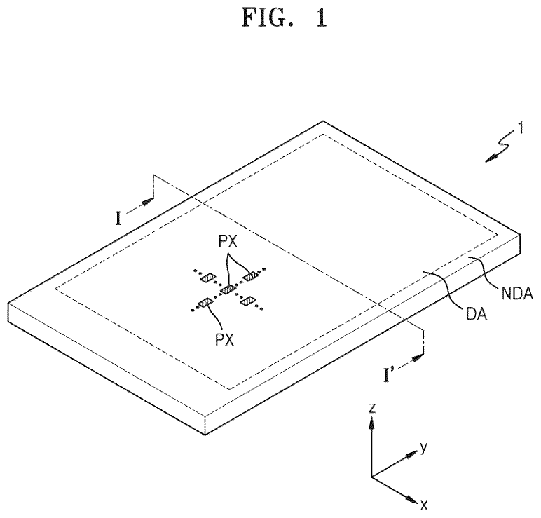

FIG. 1 is a schematic perspective view of a display device according to an embodiment.

Referring to FIG. 1, a display device 1 may include a display area DA and a peripheral area NDA outside the display area DA. The display device 1 may provide an image through an array of sub-pixels PX that are two-dimensionally arranged in the display area DA.

Each sub-pixel PX of the display device 1 may be a region where light having a certain color may be emitted, and the display device 1 may provide an image by using light emitted from the sub-pixels PX. For example, each sub-pixel PX may emit red light, green light, blue light, or white light.

Each sub-pixel PX may emit light of a certain color by using a light-emitting diode, for example, an organic light-emitting diode. Each organic light-emitting diode may be configured to emit, for example, red, green, blue, or white light. Each organic light-emitting diode may be connected to a sub-pixel circuit including a thin-film transistor and a capacitor.

The peripheral area NDA is a region in which an image is not displayed and may surround the display area DA entirely. A driver or a main power line configured to provide electric signals or power to the sub-pixel circuits may be arranged in the peripheral area NDA. A pad may be arranged in the peripheral area NDA, wherein the pad is a region to which electronic elements or a printed circuit board may be electrically connected.

As shown in FIG. 1, the display area DA may have a polygonal shape such as a quadrangular shape. For example, the display area DA may have a rectangular shape in which a horizontal length is greater than a vertical length, a rectangular shape in which a horizontal length is less than a vertical length, or a square shape. For example, the display area DA may have various shapes such as an elliptical shape or a circular shape.

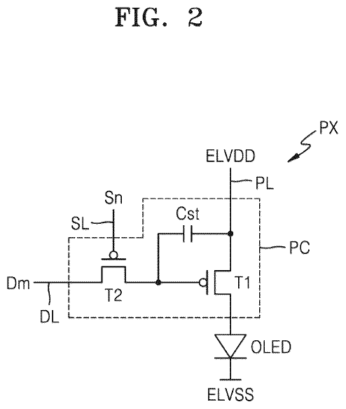

FIG. 2 is a view of a light-emitting diode of a sub-pixel of the display device 1 and a sub-pixel circuit connected thereto according to an embodiment.

Referring to FIG. 2, an organic light-emitting diode OLED, which is a light-emitting diode, is connected to a sub-pixel circuit PC. The sub-pixel circuit PC may include a first thin-film transistor T1, a second thin-film transistor T2, and a storage capacitor Cst.

The second thin-film transistor T2 is a switching thin-film transistor, may be electrically connected to a scan line SL and a data line DL, and may be configured to transmit a data signal Dm, which is input through the data line DL, to the first thin-film transistor T1 according to a scan voltage or a scan signal Sn that is input through the scan line SL.

The storage capacitor Cst may be electrically connected to the second thin-film transistor T2 and a driving voltage line PL and may be configured to store a voltage corresponding to a difference between a voltage from the second thin-film transistor T2 and a driving voltage ELVDD provided to the driving voltage line PL.

The first thin-film transistor T1 is a driving thin-film transistor, may be electrically connected to the driving voltage line PL and the storage capacitor Cst, and may be configured to control a driving current flowing in the organic light-emitting diode OLED from the driving voltage line PL according to a value of the voltage stored in the storage capacitor Cst. The organic light-emitting diode OLED may be configured to emit light having a preset brightness corresponding to the driving current. A sub-pixel electrode (e.g., an anode) of the organic light-emitting diode OLED may be connected to the sub-pixel circuit PC. An opposite electrode (e.g., a cathode) of the organic light-emitting diode OLED may be configured to receive a common voltage ELVSS.

FIG. 2 illustrates that the sub-pixel circuit PC includes two thin-film transistors and one storage capacitor. However, in an embodiment, the number of thin-film transistors or the number of storage capacitors may vary according to the design of the sub-pixel circuit PC.

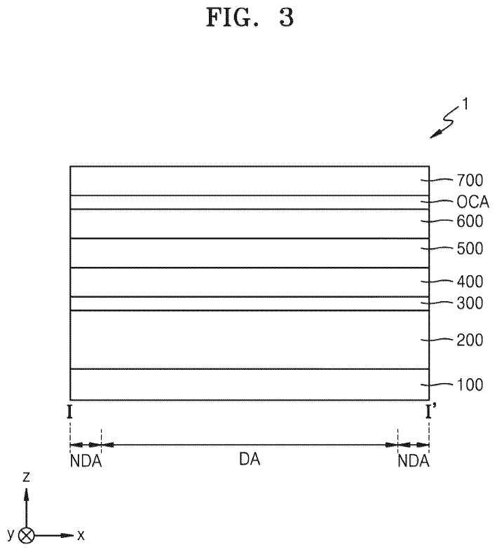

FIG. 3 is a schematic cross-sectional view of the display device 1 taken along line I-I′ of FIG. 1, according to an embodiment.

Referring to FIG. 3, the display device 1 may include a substrate 100, a display layer 200, a low reflection layer 300, an encapsulation layer 400, a touch sensor layer 500, an optical control layer 600, an adhesive layer OCA, and a cover window 700.

The substrate 100 may include glass or a polymer resin. For example, the polymer resin may include polyether sulfone, polyacrylate, polyetherimide, polyethylene naphthalate, polyethylene terephthalate, polyphenylene sulfide, polyarylate, polyimide, polycarbonate, cellulose acetate propionate, or the like. The substrate 100 including the polymer resin may be flexible, rollable, or bendable. The substrate 100 may have a multi-layered structure including a layer, which includes a polymer resin, and an inorganic layer (not shown).

The display layer 200 may include a light-emitting diode, a thin-film transistor, and insulating layers therebetween, the thin-film transistor being electrically connected to the light-emitting diode, for example, an organic light-emitting diode.

The low reflection layer 300 may be disposed on the display layer 200, and the encapsulation layer 400 may be disposed on the low reflection layer 300. For example, the display layer 200 and/or the low reflection layer 300 may be sealed by the encapsulation layer 400. In an embodiment, the low reflection layer 300 may be omitted. In this case, the encapsulation layer 400 may be directly disposed on the display layer 200. The encapsulation layer 400 may include at least one inorganic encapsulation layer and at least one organic encapsulation layer.

In an embodiment, an encapsulation substrate (not shown) including glass may be provided instead of the encapsulation layer 400. The encapsulation substrate may be disposed on the display layer 200, and the display layer 200 may be disposed between the substrate 100 and the encapsulation substrate. A gap may exist between the encapsulation substrate and the display layer 200 and may be filled with fillers.

The touch sensor layer 500 may be disposed on the encapsulation layer 400. The touch sensor layer 500 may sense an external input, e.g., a touch from an object, such as a finger or a stylus pen, and allow the display device 1 to obtain coordinate information corresponding to a touch location. The touch sensor layer 500 may include a touch electrode and trace lines connected to the touch electrode. The touch sensor layer 500 may sense an external input by using a self-capacitance method or a mutual capacitance method.

The touch sensor layer 500 may be directly disposed on the encapsulation layer 400. In other embodiments, the touch sensor layer 500 may be formed separately, and then attached to the encapsulation layer 400 through an adhesive layer such as an optically clear adhesive.

The optical control layer 600 may be arranged on the touch sensor layer 500. The optical control layer 600 may reduce the reflectivity of external light that is incident to the display device 1 from the outside through the cover window 700.

The optical control layer 600 may include color filters. The color filter may have a color corresponding to light emitted from an emission layer located under each color filter. The optical control layer 600 may further include a light-shielding layer to be described later as well as the color filter to improve reflection characteristics. In addition, the optical control layer 600 may include an overcoat layer capable of flattening the top surfaces of a plurality of color filters.

The cover window 700 may be disposed on the optical control layer 600. The cover window 700 may protect layers covered by the cover window 700. The cover window 700 may be formed separately and attached to the optical control layer 600 by the adhesive layer OCA disposed between the cover window 700 and the optical control layer 600. The adhesive layer OCA may be, for example, an optically transparent adhesive. In other examples, the cover window 700 may be directly disposed on the optical control layer 600.

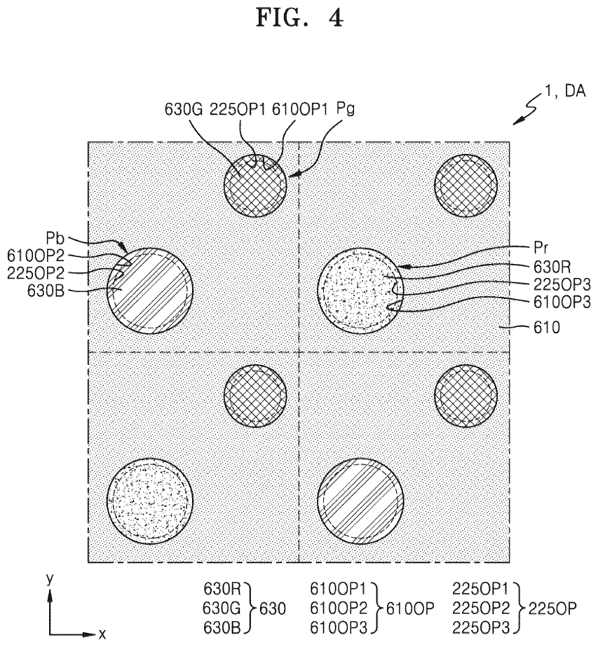

FIG. 4 is a schematic plan view of a portion of the display device 1 according to an embodiment. FIG. 4 illustrates a plan view of a light-shielding layer 610 for convenience.

Referring to FIG. 4, the display device 1 may include a plurality of sub-pixels. The plurality of sub-pixels may include a red sub-pixel Pr, a blue sub-pixel Pb, and a green sub-pixel Pg. The plurality of sub-pixels may include light-emitting diodes emitting light of respective colors. For example, the red sub-pixel Pr may emit light in a wavelength band of about 580 nm to about 780 nm, the blue sub-pixel Pb may emit light in a wavelength band of about 380 nm to about 495 nm, and the green sub-pixel Pg may emit light in a wavelength band of about 495 nm to about 580 nm.

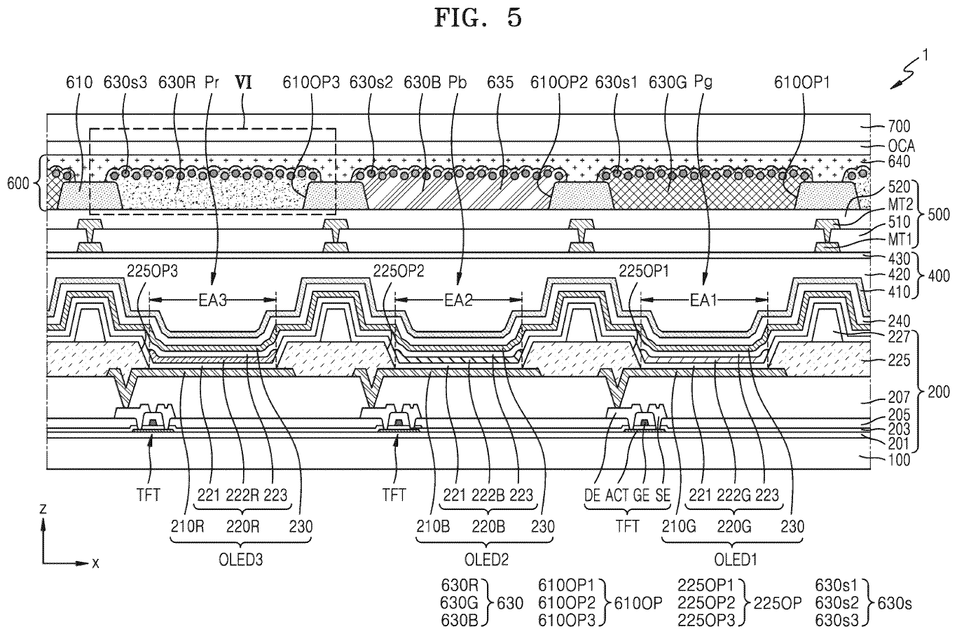

A bank layer 225 (see FIG. 5) may include a lower opening 225OP that defines the emission area of each sub-pixel. The light-emitting diode may include a sub-pixel electrode, an opposite electrode, and an emission layer arranged therebetween, the bank layer 225 (see FIG. 5) may cover edges of the sub-pixel electrode, and the lower opening 225OP of the bank layer 225 (see FIG. 5) may expose a central portion of the sub-pixel electrode. The emission layer of the light-emitting diode may be arranged within the lower opening 225OP of the bank layer 225 (see FIG. 5). Specifically, the bank layer 225 (see FIG. 5) may include a first lower opening 225OP1 defining the emission area of the green sub-pixel Pg, a second lower opening 225OP2 defining the emission area of the blue sub-pixel Pb, and a third lower opening 225OP3 defining the emission area of the red sub-pixel Pr.

As shown in FIG. 4, the first lower opening 225OP1, the second lower opening 225OP2, and the third lower opening 225OP3 may each have a circular shape when viewed from a direction perpendicular to the substrate 100 (see FIG. 5). In other words, the emission area of each of the green sub-pixel Pg, the blue sub-pixel Pb, and the red sub-pixel Pr may have a circular shape when viewed from a direction perpendicular to the substrate 100 (see FIG. 5). However, one or more embodiments are not limited thereto. For example, the first lower opening 225OP1, the second lower opening 225OP2, and the third lower opening 225OP3 may each have a polygonal shape.

The light-shielding layer 610 of the optical control layer 600 (see FIG. 3) described above may be arranged on the bank layer 225 (see FIG. 5) and the light-emitting diode. The light-shielding layer 610 may include upper openings 610OP respectively corresponding to the emission areas. Specifically, the light-shielding layer 610 may include a first upper opening 610OP1 corresponding to the green sub-pixel Pg and overlapping the first lower opening 225OP1, a second upper opening 610OP2 corresponding to the blue sub-pixel Pb and overlapping the second lower opening 225OP2, and a third upper opening 610OP3 corresponding to the red sub-pixel Pr and overlapping the third lower opening 225OP3.

The upper opening 610OP of the light-shielding layer 610 may be filled with a color filter layer 630 of the optical control layer 600 (see FIG. 3). Specifically, the first upper opening 610OP1 may be filled with a first color filter 630G, the second upper opening 610OP2 may be filled with a second color filter 630B, and the third upper opening 610OP3 may be filled with a third color filter 630R.

Similarly to the lower opening 225OP, the upper opening 610OP may also have a circular shape when viewed from a direction perpendicular to the substrate 100 (see FIG. 5). However, one or more embodiments are not limited thereto, and the shape of the upper opening 610OP may be modified according to the shape of the lower opening 225OP. However, an area of the upper opening 610OP may be greater than that of the lower opening 225OP. This configuration is designed to maximize the efficiency of light emitted from the emission area. For example, a planar area of the first upper opening 610OP1 may be greater than that of the first lower opening 225OP1. That is, in a plan view, the bank layer 225 (see FIG. 5) may be arranged to protrude further towards the emission area (or the center of each sub-pixel) than the light-shielding layer 610.

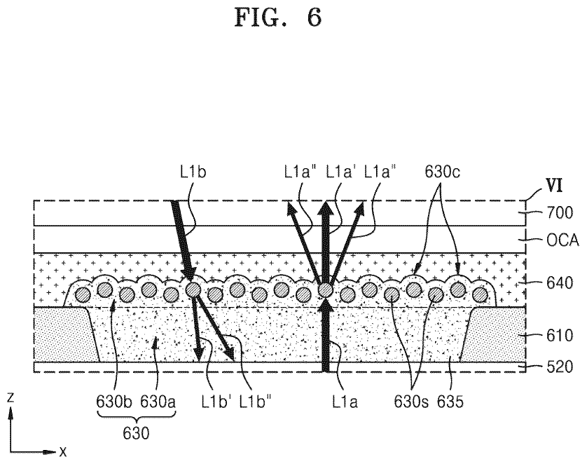

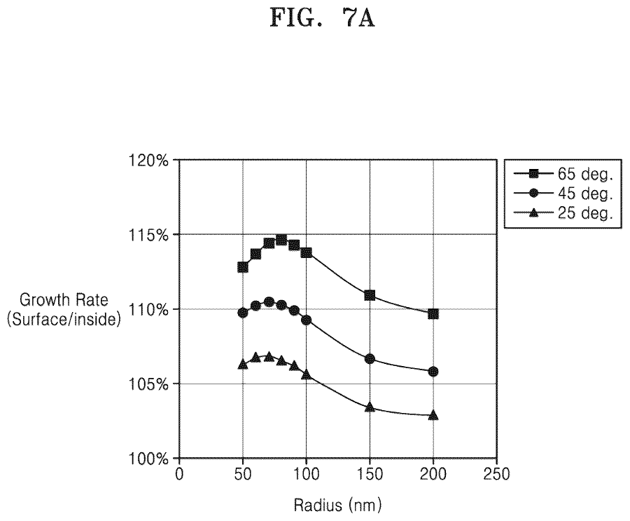

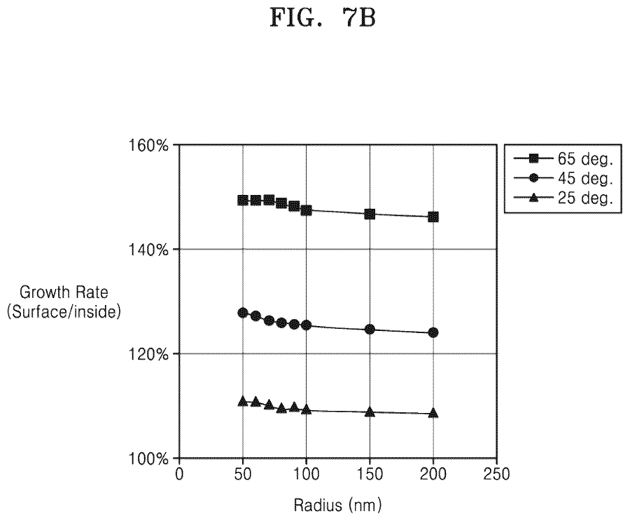

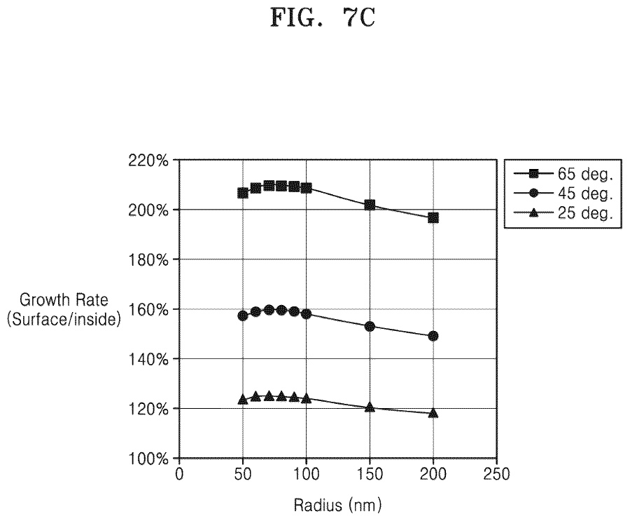

FIG. 5 is a schematic cross-sectional view of a portion of the display device 1 according to an embodiment. FIG. 6 is an enlarged schematic cross-sectional view of a region VI of the display device 1 of FIG. 5, according to an embodiment. FIGS. 7A to 7C are graphs illustrating scattering characteristics according to a measurement angle of light emitted from an organic light-emitting diode included in the display device 1 according to an embodiment.

Referring to FIG. 5, the display device 1 may include the substrate 100, the display layer 200, the encapsulation layer 400, the touch sensor layer 500, the optical control layer 600, the adhesive layer OCA, and the cover window 700.

The display device 1 may include a plurality of sub-pixels arranged in the display area DA (see FIG. 4). Each sub-pixel may include, for example, red light, green light, or blue light. The plurality of sub-pixels may include sub-pixels emitting light of different colors, for example, the green sub-pixel Pg, the blue sub-pixel Pb, and the red sub-pixel Pr. The green sub-pixel Pg, the blue sub-pixel Pb, and the red sub-pixel Pr may each be provided in plurality.

The display layer 200 may be disposed on the substrate 100. The display layer 200 may include a sub-pixel circuit layer and a light-emitting diode layer. The sub-pixel circuit layer may include thin-film transistors TFT, a buffer layer 201, a gate insulating layer 203, an interlayer insulating layer 205, and a planarization layer 207, which are insulating layers.

The buffer layer 201 may be disposed on the substrate 100, may reduce or block penetration of foreign materials, moisture, or external air from below the substrate 100, and provide a flat surface on the substrate 100. The buffer layer 201 may include an inorganic material, an organic material, or an organic/inorganic composite material, and include a single layer or a multi-layer including an inorganic material and an organic material, the inorganic material including oxide or nitride. A barrier layer (not shown) may be further disposed between the substrate 100 and the buffer layer 201, the barrier layer blocking penetration of external air. For example, the buffer layer 201 may include silicon oxide or silicon nitride.

The thin-film transistor TFT may be disposed on the buffer layer 201. The thin-film transistor TFT may include a semiconductor layer ACT, a gate electrode GE, a source electrode SE, and a drain electrode DE. The thin-film transistor TFT may be connected to an organic light-emitting diode to drive the organic light-emitting diode.

The semiconductor layer ACT may be disposed on the buffer layer 201. The semiconductor layer ACT may include polycrystalline silicon or amorphous silicon. In other embodiments, the semiconductor layer ACT may include an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, a source region, and a drain region, the source region and the drain region being doped with impurities.

The gate electrode GE, the source electrode SE, and the drain electrode DE may each include various conductive materials. In an embodiment, the gate electrode GE may include at least one of molybdenum (Mo), aluminum (Al), copper (Cu), and titanium (Ti). For example, the gate electrode GE may include a single Mo layer or a three-layered structure including a Mo layer, an Al layer, and a Mo layer. In an embodiment, the source electrode SE and the drain electrode DE may each include at least one of copper (Cu), titanium (Ti), and aluminum (Al). For example, the source electrode SE and the drain electrode DE may each include a three-layered structure of a Ti layer, an Al layer, and a Ti layer.

To secure insulation between the semiconductor layer ACT and the gate electrode GE, the gate insulating layer 203 may be disposed between the semiconductor layer ACT and the gate electrode GE. The interlayer insulating layer 205 may be disposed on the gate electrode GE, and the source electrode SE and the drain electrode DE may be disposed on the interlayer insulating layer 205.

The gate insulating layer 203 and the interlayer insulating layer 205 may each include an inorganic material such as silicon oxide, silicon nitride, and/or silicon oxynitride. The gate insulating layer 203 and the interlayer insulating layer 205 may each be formed by, for example, chemical vapor deposition (CVD) or atomic layer deposition (ALD).

The planarization layer 207 may be disposed on the thin-film transistor TFT. To provide a flat upper surface, the planarization layer 207 is formed and then chemical mechanical polishing may be performed on the upper surface of the planarization layer 207. The planarization layer 207 may include a general-purpose polymer such as photosensitive polyimide, polyimide, polycarbonate (PC), benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer. Although the planarization layer 207 is illustrated as a single layer in FIG. 5, the planarization layer 207 may include a multi-layer in an embodiment. Each of the first sub-pixel electrode 210G of the first organic light-emitting diode OLED1, the second sub-pixel electrode 210B of the second organic light-emitting diode OLED2, and the third sub-pixel electrode 210R of the third organic light-emitting diode OLED3 may be electrically connected to the thin-film transistors TFT through contact holes of the planarization layer 207.

The light-emitting diode layer may be disposed on the sub-pixel circuit layer. In an embodiment, the light-emitting diode layer may include the first organic light-emitting diode OLED1, the second organic light-emitting diode OLED2, the third organic light-emitting diode OLED3, the bank layer 225, and a spacer 227.

The first organic light-emitting diode OLED1, the second organic light-emitting diode OLED2, and the third organic light-emitting diode OLED3 may be disposed on the sub-pixel circuit layer. The first organic light-emitting diode OLED1 may have a stack structure including the first sub-pixel electrode 210G, a first intermediate layer 220G, which includes a first common layer 221, a first emission layer 222G, and a second common layer 223, and an opposite electrode 230, the second organic light-emitting diode OLED2 may include the second sub-pixel electrode 210B, a second intermediate layer 220B, which includes the first common layer 221, a second emission layer 222B, and the second common layer 223, and the opposite electrode 230, and the third organic light-emitting diode OLED3 may include the third sub-pixel electrode 210R, a third intermediate layer 220R, which includes the first common layer 221, a third emission layer 222R, and the second common layer 223, and the opposite electrode 230.

The first sub-pixel electrode 210G, the second sub-pixel electrode 210B, and the third sub-pixel electrode 230R may be arranged on the planarization layer 207. The first sub-pixel electrode 210G, the second sub-pixel electrode 210B, and the third sub-pixel electrode 210R may be arranged apart from each other. The first sub-pixel electrode 210G, the second sub-pixel electrode 210B, and the third sub-pixel electrode 230R may each be a reflective electrode. Each of the first sub-pixel electrode 210G, the second sub-pixel electrode 210B, and the third sub-pixel electrode 210R may include a reflective layer and a transparent or semi-transparent conductive layer on the reflective layer, the reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent or semi-transparent conductive layer may include at least one of indium tin oxide (ITO), indium zinc oxide (IZO), zinc oxide (ZnO), indium oxide (In₂O₃), indium gallium oxide (IGO), and aluminum zinc oxide (AZO).

The bank layer 225 may be arranged on the first sub-pixel electrode 210G, the second sub-pixel electrode 210B, and the third sub-pixel electrode 230R. The bank layer 225 may include the lower openings 225OP that respectively overlap the first sub-pixel electrode 210G, the second sub-pixel electrode 210B, and the third sub-pixel electrode 210R and expose central portions of the first sub-pixel electrode 210G, the second sub-pixel electrode 210B, and the third sub-pixel electrode 210R, respectively. The bank layer 225 may cover edges of the first sub-pixel electrode 210G, the second sub-pixel electrode 210B, and the third sub-pixel electrode 210R and may increase distances between the edges of the first sub-pixel electrode 210G, the second sub-pixel electrode 210B, and the third sub-pixel electrode 210R and the opposite electrode 230, thereby preventing arcs from being generated at the edges of the first sub-pixel electrode 210G, the second sub-pixel electrode 210B, and the third sub-pixel electrode 210R.

The lower openings 225OP of the bank layer 225 may define a first emission area EA1 to a third emission area EA3 of the first organic light-emitting diode OLED1 to the third organic light-emitting diode OLED3 that are respectively included in the sub-pixels. As shown in FIG. 5, the bank layer 225 may include the first lower opening 225OP1 that defines the first emission area EA1 of the first organic light-emitting diode OLED1 of the green sub-pixel Pg. In addition, the bank layer 225 may include the second lower opening 225OP2 defining the second emission area EA2 of the second organic light-emitting diode OLED2 of the blue sub-pixel Pb and the third lower opening 225OP3 defining the third emission area EA3 of the third organic light-emitting diode OLED3 of the red sub-pixel Pr.

The bank layer 225 may include an organic insulating material. in other examples, the bank layer 225 may include an inorganic insulating material such as silicon nitride or silicon oxide. In an embodiment, the bank layer 225 may include an organic insulating material and an inorganic insulating material.

In an embodiment, the bank layer 225 may include a light-shielding material. For example, the light-shielding material of the bank layer 225 may be black. The light-shielding material may include carbon black, carbon nanotubes, resin or paste including a black dye, metal particles such as Ni, Al, Mo, or an alloy thereof, metal oxide particles, metal nitride particles, or the like. When the bank layer 225 includes the light-shielding material, external light reflection from metal structures arranged under the bank layer 225 may decrease.

The spacer 227 may be arranged on the bank layer 225. The spacer 227 may include an organic insulating material such as polyimide. In other embodiments, the spacer 227 may include an inorganic insulating material such as silicon nitride or silicon oxide, or include an organic insulating material and an inorganic insulating material. In an embodiment, the spacer 227 may include a material that is different from that of the bank layer 225 including the aforementioned light-shielding material, and the spacer 227 and the bank layer 225 may be formed through separate processes. In an embodiment, the spacer 227 may include a same material as the bank layer 225. In this case, the bank layer 225 and the spacer 227 may be simultaneously formed during a mask process that uses a half-tone mask.

Intermediate layers may be arranged on the first sub-pixel electrode 210G, the second sub-pixel electrode 210B, the third sub-pixel electrode 210R, and the bank layer 225. As described above, the intermediate layer may include the first common layer 221, the emission layer, and the second common layer 223.

The first emission layer 222G, the second emission layer 222B, and the third emission layer 222R may be arranged within the first lower opening 225OP1, the second lower opening 225OP2, and the third lower opening 225OP3 of the bank layer 225, respectively. The first emission layer 222G, the second emission layer 222B, and the third emission layer 222R may each include an organic material containing a fluorescent material or a phosphorescent material capable of emitting green light, blue light, or red light. The organic material may include a low molecular weight organic material or a polymer organic material.

The first common layer 221 and the second common layer 223 may be arranged on and under the emission layer, respectively. The first common layer 221 may include, for example, a hole transport layer (HTL) or both an HTL and a hole injection layer (HIL). The second common layer 223 may include, for example, an electron transport layer (ETL) or both an ETL and an electron injection layer (EIL). In an embodiment, the second common layer 223 may not be provided.

While the emission layers are respectively arranged on the sub-pixels to correspond to the first lower opening 225OP1 to the third lower opening 225OP3 of the bank layer 225, the first common layer 221 and the second common layer 223 may each be integrally formed to entirely cover the substrate 100. In other words, the first common layer 221 and the second common layer 223 may each be integrally formed to entirely cover the display area DA (see FIG. 4) of the substrate 100.

The opposite electrode 230 may be a cathode which is an electron injection electrode. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. In other examples, the opposite electrode 230 may further include a layer on the (semi) transparent layer, the layer including ITO, IZO, ZnO, or In₂O₃.

In an embodiment, a capping layer 240 may be further disposed on the display layer 200. The capping layer 240 may be arranged on the first organic light-emitting diode OLED1 to the third organic light-emitting diode OLED3. In an embodiment, the capping layer 240 may improve the emission efficiency of the first organic light-emitting diode OLED1 to the third organic light-emitting diode OLED3 based on the principle of constructive interference.

The capping layer 240 may be an organic capping layer including an organic material, an inorganic capping layer including an inorganic material, or a composite capping layer including an organic material and an inorganic material. For example, the capping layer 240 is a carbocyclic compound, a heterocyclic compound, an amine group-containing compound, porphine derivatives, phthalocyanine derivatives, naphthalocyanine derivatives, alkali metal complexes, alkali earth metal complexes, or an arbitrary combination thereof. Carbocyclic compounds, heterocyclic compounds, and amine group-containing compounds may optionally be substituted with substituents including O, N, S, Se, Si, F, Cl, Br, I, or an arbitrary combination thereof.

The encapsulation layer 400 may be disposed on the capping layer 240. The encapsulation layer 400 may include at least one inorganic encapsulation layer and at least one organic encapsulation layer. For example, as shown in FIG. 5, the encapsulation layer 400 may include a first inorganic encapsulation layer 410, an organic encapsulation layer 420, and a second inorganic encapsulation layer 430, which are sequentially stacked.

The first inorganic encapsulation layer 410 and the second inorganic encapsulation layer 430 may include an inorganic insulating material such as silicon oxide, silicon nitride, silicon oxynitride, aluminum oxide, titanium oxide, tantalum oxide, hafnium oxide, or zinc oxide. The first inorganic encapsulation layer 410 and the second inorganic encapsulation layer 430 may each have a single-layered structure or a multi-layered structure including the inorganic insulating material.

The organic encapsulation layer 420 may alleviate internal stress of the first inorganic encapsulation layer 410 and/or the second inorganic encapsulation layer 430. The organic encapsulation layer 420 may include a polymer-based material. For example, the organic encapsulation layer 420 may include polyethylene terephthalate, polyethylene naphthalate, polycarbonate, polyimide, polyethylene sulfonate, polyoxymethylene, polyarylate, hexamethyldisiloxane, an acryl-based resin (e.g., polymethylmethacrylate, poly acrylic acid, etc.), or an arbitrary combination thereof.

The encapsulation layer 400 may have a multi-layered structure including the first inorganic encapsulation layer 410, the organic encapsulation layer 420, and the second inorganic encapsulation layer 430. In this case, even if cracks occur in the encapsulation layer 400, the cracks may not propagate between the first inorganic encapsulation layer 410 and the organic encapsulation layer 420 or between the organic encapsulation layer 420 and the second inorganic encapsulation layer 430. The encapsulation layer 400 may prevent or reduce external moisture, oxygen, or the like from penetrating to the display area DA (see FIG. 1).

The touch sensor layer 500 may be disposed on the encapsulation layer 400. The touch sensor layer 500 may include a first touch electrode MT1, a first touch insulating layer 510, a second touch electrode MT2, and a second touch insulating layer 520. The first touch electrode MT1 may be directly disposed on the encapsulation layer 400. For example, the first touch electrode MT1 may be directly disposed on the second inorganic encapsulation layer 430 of the encapsulation layer 400. However, the disclosure is not limited thereto.

In an embodiment, the touch sensor layer 500 may include an insulating layer (not shown) between the first touch electrode MT1 and the encapsulation layer 400. In this case, the insulating layer may be disposed on the second inorganic encapsulation layer 430 of the encapsulation layer 400 to planarize a surface on which the first touch electrode MT1 and the like is disposed. The insulating layer may include an inorganic insulating material such as silicon oxide, silicon nitride, and silicon oxynitride. In an embodiment, the insulating layer may include an organic insulating material.

The first touch insulating layer 510 may be arranged on the first touch electrode MT1. The first touch insulating layer 510 may include an inorganic material or an organic material. In the case where the first touch insulating layer 510 includes an inorganic material, the first touch insulating layer 510 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In the case where the first touch insulating layer 510 includes an organic material, the first touch insulating layer 510 may include at least one of an acryl-based resin, a methacryl-based resin, a polyisoprene, a vinyl-based resin, an epoxy-based resin, a urethane-based resin, a cellulose resin, and a perylene-based resin.

The second touch electrode MT2 may be disposed on the first touch insulating layer 510. The second touch electrode MT2 may serve as a sensor that senses a user's touch input. The first touch electrode MT1 may serve as a connector that is connected to the second touch electrode MT2 patterned in one direction. In an embodiment, both the first touch electrode MT1 and the second touch electrode MT2 may serve as sensors. In this case, the first touch electrode MT1 may be electrically connected to the second touch electrode MT2 through a contact hole. In the case where both the first touch electrode MT1 and the second touch electrode MT2 may serve as sensors, a resistance of a touch electrode is reduced and a user's touch input may be swiftly sensed.

In an embodiment, the first touch electrode MT1 and the second touch electrode MT2 may have a structure through which light emitted from the light-emitting diode passes, for example, a mesh structure. In this case, the first touch electrode MT1 and the second touch electrode MT2 may not overlap the emission area of the light-emitting diode.

The first touch electrode MT1 and the second touch electrode MT2 may each include a metal layer or a transparent conductive layer. The metal layer may include at least one of molybdenum (Mo), silver (Ag), titanium (Ti), copper (Cu), aluminum (Al), and an alloy thereof. The transparent conductive layer may include a transparent conductive oxide such as indium tin oxide (ITO), zinc oxide (ZnO), and indium tin zinc oxide (ITZO), a conductive polymer such as poly(3,4-ethylenedioxythiophene) (PEDOT), a metal nanowire, a carbon nanotube, or graphene.

The second touch insulating layer 520 may be disposed on the second touch electrode MT2. The second touch insulating layer 520 may include an inorganic material or an organic material. In the case where the second touch insulating layer 520 includes an inorganic material, the second touch insulating layer 520 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In the case where the second touch insulating layer 520 includes an organic material, the second touch insulating layer 520 may include at least one of an acryl-based resin, a methacryl-based resin, a polyisoprene, a vinyl-based resin, an epoxy-based resin, a urethane-based resin, a cellulose resin, and a perylene-based resin.

The optical control layer 600 may be arranged on the touch sensor layer 500. The optical control layer 600 may include a light-shielding layer 610, a color filter layer 630, and an overcoat layer 640. In an embodiment, the optical control layer 600 may include a first color filter 630G, a second color filter 630B, and a third color filter 630R that emit light of different colors and correspond to the first organic light-emitting diode OLED1, the second organic light-emitting diode OLED2, the third organic light-emitting diode OLED3, respectively. The first color filter 630G, the second color filter 630B, and the third color filter 630R may each be provided in plurality.

The optical control layer 600 may be arranged on the touch sensor layer 500. The optical control layer 600 may be directly arranged on the touch sensor layer 500, for example, the second touch insulating layer 520 corresponding to the uppermost portion of the touch sensor layer 500. The light-shielding layer 610 and the color filter layer 630 forming the optical control layer 600 may be directly arranged on the touch sensor layer 500.

The light-shielding layer 610 may include the upper openings 610OP that respectively correspond to the green sub-pixel Pg, the blue sub-pixel Pb, and the red sub-pixel Pr. Specifically, the light-shielding layer 610 may include the first upper opening 610OP1 corresponding to the first emission area EA1, the second upper opening 610OP2 corresponding to the second emission area EA2, and the third upper opening 610OP3 corresponding to the third emission area EA3. Light emitted from the first organic light-emitting diode OLED1 to the third organic light-emitting diode OLED3 may be emitted to the outside through the upper openings 610OP of the light-shielding layer 610.

Because the upper openings 610OP of the light-shielding layer 610 overlap the emission areas, the upper openings 610OP may be at least partially aligned with the lower openings 225OP of the bank layer 225. For example, the first upper opening 610OP1 of the light-shielding layer 610 may be at least partially aligned with the first lower opening 225OP1 of the bank layer 225, the second upper opening 610OP2 of the light-shielding layer 610 may be at least partially aligned with the second lower opening 225OP2 of the bank layer 225, and the third upper opening 610OP3 of the light-shielding layer 610 may be at least partially aligned with the third lower opening 225OP3 of the bank layer 225.

In an embodiment, a width (or size) of the upper opening 610OP of the light-shielding layer 610 may be greater than that of the emission area of its corresponding sub-pixel. For example, a size of the first upper opening 610OP1 of the light-shielding layer 610 may be greater than that of the first lower opening 225OP1 of the bank layer 225. Similarly, a size of the second upper opening 610OP2 of the light-shielding layer 610 may be greater than that of the second lower opening 225OP2 of the bank layer 225, and a size of the third upper opening 610OP3 of the light-shielding layer 610 may be greater than that of the third lower opening 225OP3 of the bank layer 225.

In an embodiment, a width (or size) of the upper opening 610OP of the light-shielding layer 610 may be substantially the same as that of the emission area of its corresponding sub-pixel. For example, a size of the first upper opening 610OP1 of the light-shielding layer 610 may be substantially the same as that of the first lower opening 225OP1 of the bank layer 225. Similarly, a size of the second upper opening 610OP2 of the light-shielding layer 610 may be substantially the same as that of the second lower opening 225OP2 of the bank layer 225, and a size of the third upper opening 610OP3 of the light-shielding layer 610 may be substantially the same as that of the third lower opening 225OP3 of the bank layer 225.

The light-shielding layer 610 may include an organic insulating material. In other embodiments, the light-shielding layer 610 may include an inorganic insulating material, such as SiNₓ or SiO₂. In some embodiments, the light-shielding layer 610 may include an organic insulating material and an inorganic insulating material.

In an embodiment, the light-shielding layer 610 may include a light-shielding material. For example, the light-shielding material of the light-shielding layer 610 may be black. The light-shielding material may include carbon black, carbon nanotubes, resin or paste including a black dye, metal particles such as Ni, Al, Mo, and an alloy thereof, metal oxide particles, metal nitride particles, or the like. When the light-shielding layer 610 includes the light-shielding material, external light reflection from metal structures arranged under the light-shielding layer 610 may be reduced.

The color filter layer 630 may be arranged on the light-shielding layer 610. The color filter layer 630 may include the first color filter 630G corresponding to the green sub-pixel Pg, the second color filter 630B corresponding to the blue sub-pixel Pb, and the third color filter 630R corresponding to the red sub-pixel Pr. In an embodiment, the first color filter 630G may be a green color filter, the second color filter 630B may be a blue color filter, and the third color filter 630R may be a red color filter.

Referring to FIGS. 5 and 6, the color filter layer 630 may include a plurality of scattering particles 630s. Specifically, the color filter layer 630 may include a color filter material, the plurality of scattering particles 630s, and a base resin 635. Each of the first to third color filters 630G, 630B and 630R may include a pigment or a dye as the color filter material. For example, the first color filter 630G may include a green pigment or green dye, the second color filter 630B may include a blue pigment or blue dye, and the third color filter 630R may include a red pigment or red dye.

The base resin 635 is a medium in which dyes and/or pigments are dispersed and may include various resin compositions that may generally be referred to as binders. For example, the base resin 635 may be an acrylic resin, a urethane resin, a silicone resin, an epoxy resin, or the like. However, the base resin is not limited thereto, and a polymer material capable of dispersing the plurality of scattering particles 630s, the pigment, and/or the dye may be included, as necessary.

In an embodiment, the plurality of scattering particles 630s may be disposed in an upper area of the color filter layer 630. The “upper area” may refer to a portion of the color filter layer 630 that is far from the organic light-emitting diode OLED and is close to the cover window 700. That is, the upper area of the color filter layer 630 may be a partial area above the color filter layer 630 based on a direction toward the front surface of the display device 1. That is, the plurality of scattering particles 630s may be positioned close to the upper surfaces of each of the first color filter 630G, the second color filter 630B, and the third color filter 630R. In other words, the color filter layer 630 may include a first sub-layer 630a and a second sub-layer 630b disposed on the first sub-layer 630a. The first sub-layer 630a may be a layer formed of the base resin 635 and the color filter material, and the second sub-layer 630b may be a layer including the color filter material, the base resin 635, and the plurality of scattering particles 630s.

As the plurality of scattering particles 630s are disposed in the upper area of the color filter layer 630, the upper surface of the color filter layer 630 may include a plurality of convex portions 630c protruding by the plurality of scattering particles 630s. That is, the color filter layer 630 may have a curved upper surface due to the plurality of convex portions 630c.

In an embodiment, the plurality of scattering particles 630s may include silica particles. Specifically, the plurality of scattering particles 630s may include silica particles surface-treated to be hydrophobic (or liquid repellent). The surface-treated silica particles may be formed by surface-treating the silica particles with a hydrophobic (or liquid repellent) material. The surface-treated silica particles may have hydrophobic (or liquid repellent) properties. For example, the plurality of scattering particles 630s may include silica particles surface-treated with fluorine.

In an embodiment, a radius of each of the plurality of scattering particles 630s may be 50 nm to 200 nm. For example, if the silica particles have a radius in the above range, a diameter of the silica particles may be larger than a thickness of the silica film formed by curing the silica precursor sol layer, and thus, the plurality of convex portions 630c may be formed on the surface of the color filter layer 630 due to the protrusion of the silica particles.

In an embodiment, a content ratio of the plurality of scattering particles 630s in the color filter layer 630 may be 0.01% to 5%. When the color filter layer 630 includes 5% or more of the scattering particles 630s, haze may excessively increase, and thus, the clarity of the image provided by the display device 1 may be rather deteriorated. In some embodiments, the content of the plurality of scattering particles 630s included in the color filter layer 630 may be different for each color filter. For example, the content of the plurality of scattering particles 630s included in the first color filter 630G, the content of the plurality of scattering particles 630s included in the second color filter 630B, and the content of the plurality of scattering particles 630s included in the third color filter 630R may be adjusted differently to improve color differences according to the viewing angle.

In the display device 1 according to an embodiment, as the plurality of scattering particles 630s are disposed in the upper area of the color filter layer 630, the plurality of convex portions 630c are formed on the upper surface of the color filter layer 630, and the color filter layer 630 may have a rough and uneven upper surface.

Referring to FIG. 6, a first outgoing light L1a emitted from the organic light-emitting diode OLED may pass through the color filter layer 630 and be emitted to the outside. At this time, as nano-sized curves are formed on the upper surface of the color filter layer 630, the first outgoing light L1a traveling in the forward direction may be scattered from the surface of the color filter layer 630 and split and emitted in various directions, such as a second outgoing light L1a′ and a third outgoing light L1a″. That is, light passing through the curved surface of the color filter layer 630 has a scattering characteristic (Lambertian emission characteristic) and is emitted in a random direction, and the front luminance and side luminance of light emitted from the display device 1 may become more uniform.

In addition, a structure in which the plurality of scattering particles 630s are placed close to the upper surface of the color filter layer 630 may have better light emission efficiency than a structure in which the plurality of scattering particles 630s are dispersed overall inside the color filter layer 630. As described above, the color filter layer 630 may be disposed in the upper opening 610OP of the light-shielding layer 610. Accordingly, some of the light emitted from the organic light-emitting diode OLED and scattered by the scattering particles 630s of the color filter layer 630 may proceed to the light-shielding layer 610 and be absorbed by the light-shielding layer 610. At this time, a structure in which scattering occurs in all areas of the color filter layer 630 may have a greater amount of light absorbed in the light-shielding layer 610 than a structure in which scattering occurs only on the upper surface of the color filter layer 630. That is, if the plurality of scattering particles 630s are disposed on the upper surface of the color filter layer 630 as shown in FIG. 6, light emission efficiency may be efficiently improved while including the same content of scattering particles.

A first incoming light L1b (or external light) incident on the display device 1 may pass through the color filter layer 630 to enter the display device 1 or may be reflected from the upper surface of the color filter layer 630. External light reflected from the upper surface of the color filter layer 630 may be visually recognized as a diffraction pattern. At this time, as nano-sized curves are formed on the upper surface of the color filter layer 630, the first incoming light L1b may be scattered from the surface of the color filter layer 630 and divided in various directions such as a second incoming light L1b′ and a third incoming light L1b″. That is, external light and reflected light are scattered by the curved surface of the color filter layer 630, so that the diffraction phenomenon may be alleviated. In particular, the upper surface of the color filter layer 630 of has the plurality of convex portions 630c formed by scattering particles 630s, and thus the surface may be rough and uneven. Through the non-uniform protrusions of the color filter layer 630, it is possible to efficiently reduce regular reflection of external light and diffraction patterns in which the same pattern is repeated.

In conclusion, in the display device 1 according to an embodiment, scattering particles 630s are disposed in the upper area of the color filter layer 630, so that the color filter layer 630 includes an unevenly curved upper surface, light emission efficiency may be increased, side luminance may be improved, and regular reflection and diffraction visibility may be efficiently reduced for external light incident on the display device 1.

In an embodiment, the plurality of scattering particles 630s included in the color filter layer 630 may be different for each color filter. For example, the diameters of the plurality of scattering particles 630s may be different for each color filter. The plurality of scattering particles 630s may include a first scattering particle 630s1 included in the first color filter 630G, a second scattering particle 630s2 included in the second color filter 630B, and a third scattering particle 630s3 included in the third color filter 630R. That is, at least one of the first scattering particles 630s1, the second scattering particles 630s2, and the third scattering particles 630s3 may have a diameter different from that of the remaining scattering particles.

FIGS. 7A to 7C are graphs illustrating scattering characteristics according to a measurement angle of light emitted from the organic light-emitting diode OLED. Specifically, FIG. 7A illustrates the scattering characteristics of green sub-pixel Pg, FIG. 7B illustrates the scattering characteristics of blue sub-pixel Pb, and FIG. 7C illustrates the scattering characteristics of red sub-pixel Pr. In FIGS. 7A to 7C, the x-axis represents a radius (nm) of the scattering particles 630s, and the y-axis represents a growth rate related to the scattering characteristics. The growth rate may satisfy Equation 1 shown below.

$$Growth Rate ( \% ) = \frac{\frac{surface Scatter {L}_{d}}{surface Scatter {L}_{0}}}{\frac{inside Scatter {L}_{d}}{inside Scatter {L}_{0}}} \times 100 \qquad [ Equation 1 ]$$

In Equation 1, “inside Scatter L₀” means the amount of light emitted when the measurement angle is 0° in a structure in which the plurality of scattering particles 630s are entirely dispersed inside the color filter layer 630, and “inside Scatter L_{d}” means the amount of light emitted when the measurement angle is a specific angle (e.g., 25°, 45°, or) 65° in a structure in which the plurality of scattering particles 630s are entirely dispersed inside the color filter layer 630. Similarly, ‘surface Scatter L₀’ means the amount of light emitted when the measurement angle is 0° in a structure in which the plurality of scattering particles 630s are disposed close to the surface of the color filter layer 630, and ‘surface Scatter L_{d}’ means the amount of light emitted when the measurement angle is a specific angle (e.g., 25°, 45°, or) 65° in a structure in which the plurality of scattering particles 630s are disposed close to the surface of the color filter layer 630.

First, referring to FIG. 7A, in the case of the green sub-pixel Pg, when the radii of the scattering particle 630s were 50 nm, 60 nm, 70 nm, 80 nm, 90 nm, 100 nm, 150 nm, and 200 nm, the growth rates were measured to be 113%, 114%, 114%, 115%, 114%, 114%, 111%, and 110%, respectively, based on the measurement angle of 65°. For green sub-pixel Pg, when the radii of the scattering particle 630s were 50 nm, 60 nm, 70 nm, 80 nm, 90 nm, 100 nm, 150 nm, and 200 nm, the growth rates were measured to be 110%, 110%, 110%, 110%, 110%, 109%, 107%, and 106%, respectively, based on the measurement angle of 45°. For green sub-pixel Pg, when the radii of the scattering particle 630s were 50 nm, 60 nm, 70 nm, 80 nm, 90 nm, 100 nm, 150 nm, and 200 nm, the growth rates were measured to be 106%, 107%, 107%, 107%, 106%, 106%, 103%, and 103%, respectively, based on the measurement angle of 25°. In conclusion, it may be confirmed that the green sub-pixel Pg has the best growth ratio when the radius of the scattering particle 630s is 80 nm.

Referring to FIG. 7B, in the case of the blue sub-pixel Pb, when the radii of the scattering particle 630s were 50 nm, 60 nm, 70 nm, 80 nm, 90 nm, 100 nm, 150 nm, and 200 nm, the growth rates were measured to be 149%, 149%, 149%, 149%, 148%, 147%, 147%, and 146%, respectively, based on the measurement angle of 65°. For blue sub-pixel Pb, when the radii of the scattering particle 630s were 50 nm, 60 nm, 70 nm, 80 nm, 90 nm, 100 nm, 150 nm, and 200 nm, the growth rates were measured to be 128%, 127%, 126%, 126%, 126%, 126%, 125%, and 124%, respectively, based on the measurement angle of 45°. For blue sub-pixel Pb, when the radii of the scattering particle 630s were 50 nm, 60 nm, 70 nm, 80 nm, 90 nm, 100 nm, 150 nm, and 200 nm, the growth rates were measured to be 111%, 111%, 110%, 110%, 110%, 109%, 109%, and 109%, respectively, based on the measurement angle of 25°. In conclusion, it may be confirmed that the blue sub-pixel Pb has the best growth ratio when the radius of the scattering particle 630s is 70 nm or 60 nm.

Referring to FIG. 7C, in the case of the red sub-pixel Pr, when the radii of the scattering particle 630s were 50 nm, 60 nm, 70 nm, 80 nm, 90 nm, 100 nm, 150 nm, and 200 nm, the growth rates were measured to be 207%, 209%, 210%, 210%, 210%, 209%, 202%, and 197%, respectively, based on the measurement angle of 65°. For red sub-pixel Pr, when the radii of the scattering particle 630s were 50 nm, 60 nm, 70 nm, 80 nm, 90 nm, 100 nm, 150 nm, and 200 nm, the growth rates were measured to be 158%, 159%, 160%, 160%, 159%, 158%, 154%, and 150%, respectively, based on the measurement angle of 45°. For red sub-pixel Pr, when the radii of the scattering particle 630s were 50 nm, 60 nm, 70 nm, 80 nm, 90 nm, 100 nm, 150 nm, and 200 nm, the growth rates were measured to be 124%, 125%, 125%, 125%, 125%, 124%, 121%, and 119%, respectively, based on the measurement angle of 25°. In conclusion, it may be confirmed that the red sub-pixel Pr has the best growth ratio when the radius of the scattering particle 630s is 80 nm.

As may be seen from the above results, the growth rate of each sub-pixel may vary depending on the diameter of the scattering particles 630s. Accordingly, the scattering particles 630s of an appropriate diameter for each sub-pixel may be selected and included in the color filter layer 630. That is, at least one of the first scattering particles 630s1, the second scattering particles 630s2, and the third scattering particles 630s3 may have a diameter different from diameters of the others.

On the other hand, referring to the above results, it may be determined that the green sub-pixel Pg, the blue sub-pixel Pb, and the red sub-pixel Pr all have a growth rate of 100% or more regardless of the measurement angle. As described above, the growth ratio is a comparison of the light emission efficiency of “the structure in which the scattering particles are dispersed inside the color filter layer” and “the structure in which the scattering particles are disposed close to the surface of the color filter layer”. In particular, from the above results, it may be determined that the higher the measurement angle, the greater the value of the growth ratio. This means that the light emission efficiency is improved in the structure in which the scattering particles are disposed close to the surface of the color filter layer than in the structure in which the scattering particles are dispersed inside the color filter layer, and the larger the measurement angle, the greater the effect. That is, when the scattering particles 630s are disposed on the upper surface of the color filter layer 630, the front luminance and the side luminance of light emitted by the display device 1 may be more uniform.

Referring back to FIG. 5, the overcoat layer 640 may be disposed on the light-shielding layer 610 and the color filter layer 630. The overcoat layer 640 may planarize upper surfaces of the light-shielding layer 610 and the color filter layer 630. That is, the overcoat layer 640 may be integrally formed over the first color filter 630G, the second color filter 630B, and the third color filter 630R. The overcoat layer 640 is a colorless light-transmissive layer that does not have a color in the visible light band. The overcoat layer 640 may include a colorless light-transmissive organic material such as an acryl-based resin.

The cover window 700 may be disposed over the overcoat layer 640 with the adhesive layer OCA therebetween. The cover window 700 may be attached to the optical control layer 600 through the adhesive layer OCA. The adhesive layer OCA may include an optically clear adhesive. The cover window 700 may be transparent. The cover window 700 may include at least one of glass, sapphire, and plastic. For example, the cover window 700 may be ultra-thin glass (UTG) or colorless polyimide (CPI).

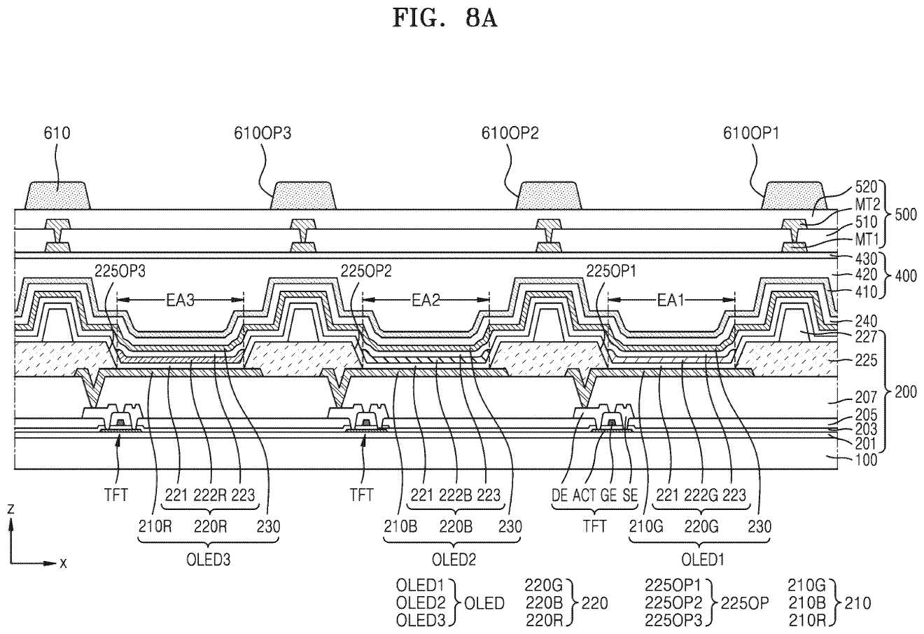

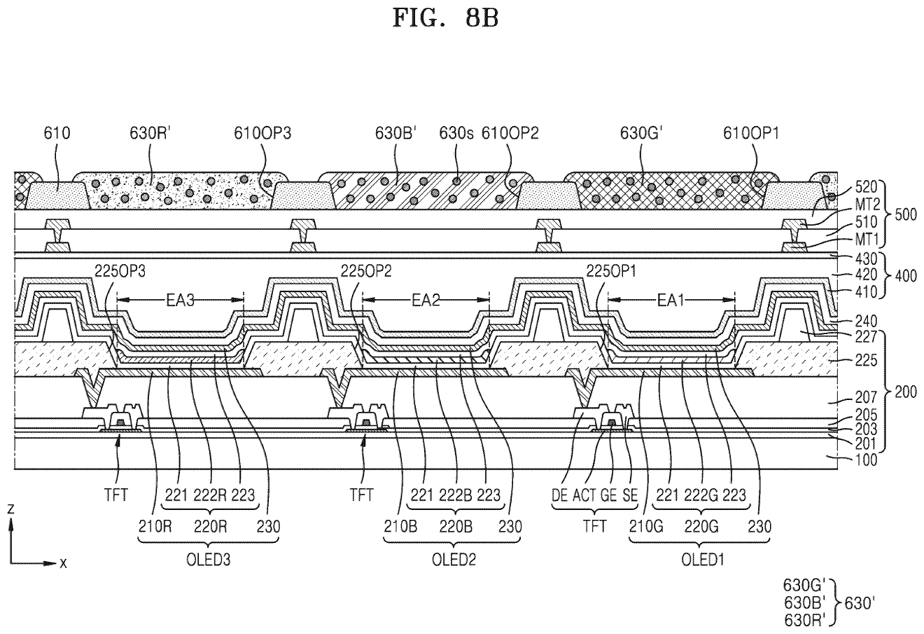

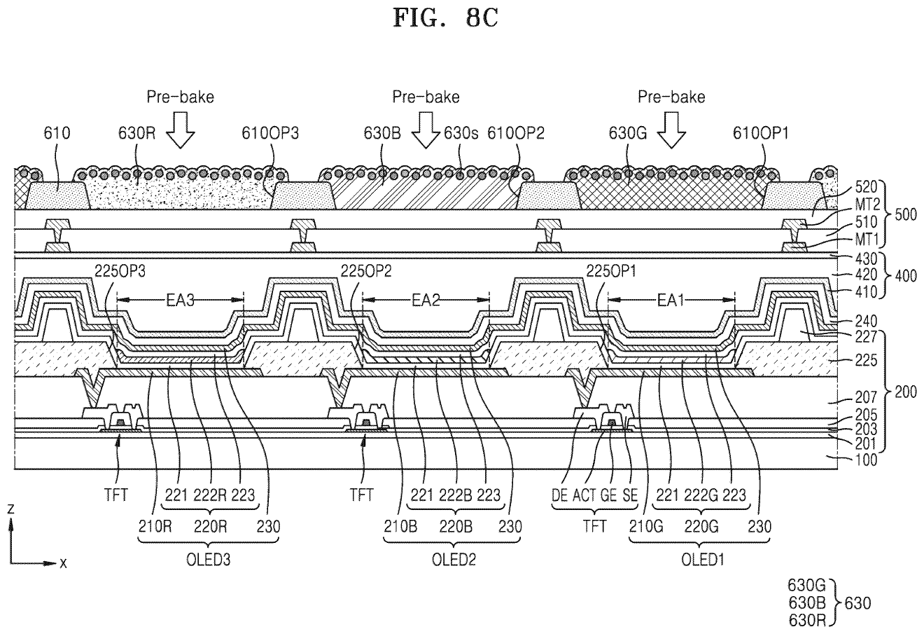

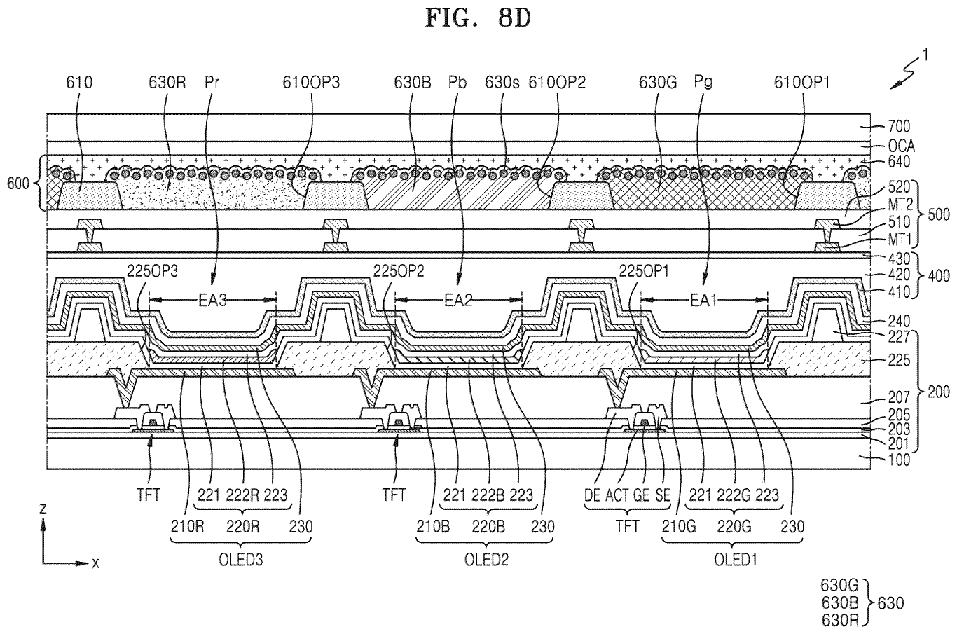

FIGS. 8A to 8D are schematic cross-sectional views illustrating a method of manufacturing the display device 1, according to an embodiment. The descriptions regarding the components indicated by the same reference symbols in FIGS. 8A to 8D are the same with those provided above with reference to FIGS. 5 and 6.

First, referring to FIG. 8A, the buffer layer 201 may be formed on the substrate 100. The thin-film transistor TFT including the gate electrode GE, the semiconductor layer ACT, the source electrode SE, and the drain electrode DE may be formed on the buffer layer 201. The planarization layer 207 may be formed on the thin-film transistor TFT, and the organic light-emitting diode OLED may be formed on the planarization layer 207.

The organic light-emitting diode OLED may include the sub-pixel electrode 210, the emission layer 222, and the opposite electrode 230. The sub-pixel electrode 210 may be formed on the planarization layer 207, and the bank layer 225 may be formed on the planarization layer 207 to cover the edges of the sub-pixel electrode 210. The lower opening 225OP exposing the central portion of the sub-pixel electrode 210 may be formed in the bank layer 225. The emission layer 222 may be formed within the lower opening 225OP of the bank layer 225, and the opposite electrode 230 may be formed to cover the emission layer 222 and the bank layer 225.

The encapsulation layer 400 may be formed on the organic light-emitting diode OLED. The encapsulation layer 400 may be formed in the order of the first inorganic encapsulation layer 410, the organic encapsulation layer 420, and the second inorganic encapsulation layer 430.

The touch sensor layer 500 may be formed on the encapsulation layer 400. The touch sensor layer 500 may be formed in the order of the first touch electrode MT1, the first touch insulating layer 510, the second touch electrode MT2, and the second touch insulating layer 520. The first touch electrode MT1 may be formed to overlap the bank layer 225, and the first touch insulating layer 510 may be formed to cover the first touch electrode MT1. The second touch insulating layer 520 may be formed on the first touch insulating layer 510 to cover the second touch electrode MT2.

The light-shielding layer 610 may be formed on the touch sensor layer 500. The upper opening 610OP may be formed in the light-shielding layer 610. The upper opening 610OP of the light-shielding layer 610 may be formed through an exposure process of irradiating light from a light source to the light-shielding layer 610 and a developing process of developing a pattern. The upper opening 610OP may include the first upper opening 610OP1, the second upper opening 610OP2, and the third upper opening 610OP3 corresponding to the first organic light-emitting diode OLED1, the second organic light-emitting diode OLED2, and the third organic light-emitting diode OLED3, respectively.

Referring to FIG. 8B, the preliminary color filter layer 630′ may be placed to fill the upper opening 610OP of the light-shielding layer 610. A first preliminary color filter 630G′ may be disposed in the first upper opening 610OP1 of the light-shielding layer 610, a second preliminary color filter 630B′ may be disposed in the second upper opening 610OP2 of the light-shielding layer 610, and a third preliminary color filter 630R′ may be disposed in the third upper opening 610OP3 of the light-shielding layer 610.

The preliminary color filter layer 630′ may include the color filter material, the plurality of scattering particles 630s, and the base resin. In an embodiment, the plurality of scattering particles 630s may be silica particles surface-treated to be hydrophobic (or liquid repellent). The plurality of scattering particles 630s may be entirely dispersed in the preliminary color filter layer 630′. In other words, the plurality of scattering particles 630s may be sporadically distributed in the preliminary color filter layer 630′.

Referring to FIG. 8C, the color filter layer 630 may be formed through a pre-baking process of heating the preliminary color filter layer 630′. The pre-baking process may be performed by heating the preliminary color filter layer 630′ to a predetermined temperature to dry the base resin and adhering the lower structure and the color filter layer 630 to each other.

In an embodiment, the plurality of scattering particles 630s may move to the upper area of the color filter layer 630 through the pre-baking process. Because the plurality of scattering particles 630s are surface-treated to be hydrophobic (or liquid repellent), when heat is applied, the plurality of scattering particles 630s may be separated from the base resin and moved in a direction of the upper surface of the color filter layer 630. In particular, because the plurality of scattering particles 630s are dispersed in the preliminary color filter layer 630′ and then move to the upper surface of the color filter layer 630, the plurality of scattering particles 630s may be unevenly and irregularly disposed near the surface of the color filter layer 630.

At this time, when the radius of each of the plurality of scattering particles 630s (e.g., silica particles) is 50 nm to 200 nm, the diameter of the silica particles may be greater than the thickness of a silica film formed by curing a silica precursor sol layer, so that the plurality of convex portions may be formed on the surface of the color filter layer 630 due to the protrusion of the silica particles. Accordingly, the color filter layer 630 may have a rough and uneven surface.

Referring to FIG. 8D, the overcoat layer 640 may be formed on the light-shielding layer 610 and the color filter layer 630. The overcoat layer 640 may planarize the upper surface of the optical control layer 600. The adhesive layer OCA and the cover window 700 may be formed on the optical control layer 600.

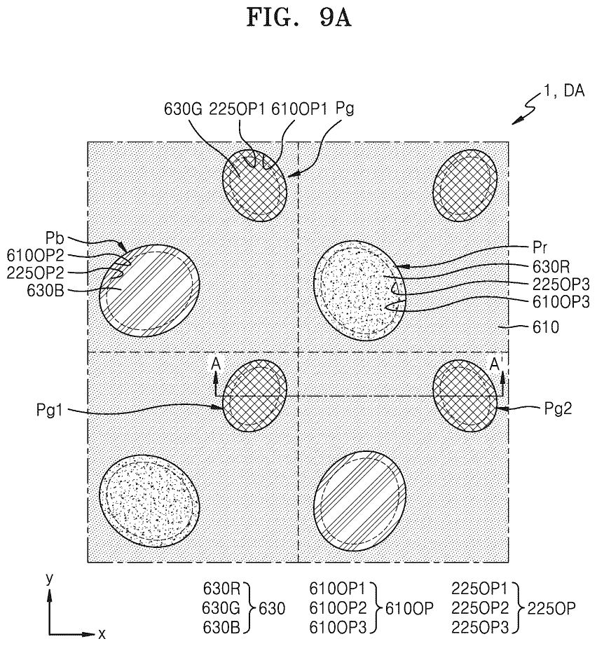

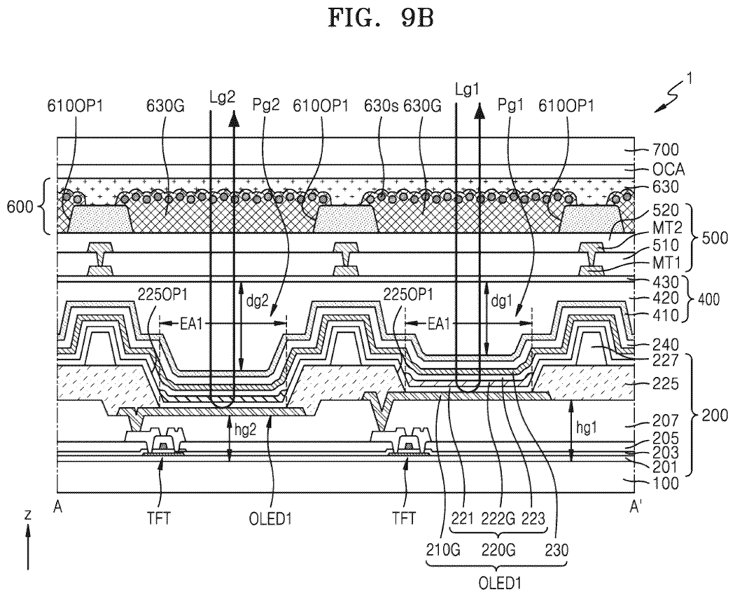

FIG. 9A is a schematic plan view of a portion of the display device 1 according to an embodiment. FIG. 9B is a schematic cross-sectional view of a portion of the display device 1 according to an embodiment. Referring to FIGS. 9A and 9B, except for the shape of the sub-pixel and the features of the planarization layer 207, other characteristics are the same as those described above with reference to FIGS. 5 and 6. The descriptions regarding the components indicated by the same reference symbols in FIGS. 9A and 9B are generally the same with those provided above with reference to FIGS. 5 and 6, and the differences therebetween are mainly described hereinafter.

First, referring to FIG. 9A, the bank layer 225 (see FIG. 9B) may include the lower opening 225OP defining an emission area of each sub-pixel, and the light-shielding layer 610 may include the upper opening 610OP corresponding to each of the plurality of emission areas. Each of the first lower opening 225OP1, the second lower opening 225OP2, and the third lower opening 225OP3 may have an elliptical shape when viewed from a direction perpendicular to the substrate 100 (see FIG. 9B). In other words, the emission area of each of the green sub-pixel Pg, the blue sub-pixel Pb, and the red sub-pixel Pr may have an elliptical shape when viewed from a direction perpendicular to the substrate 100 (see FIG. 9B). In addition, each of the first upper opening 610OP1, the second upper opening 610OP2, and the third upper opening 610OP3 in which the color filter layer 630 is disposed may have an elliptical shape when viewed from a direction perpendicular to the substrate 100 (FIG. 9B).

In an embodiment, each of the green sub-pixel Pg, the blue sub-pixel Pb, and the red sub-pixel Pr may have the elliptical shape and have different elliptical axis angles. In addition, even the sub-pixels emitting light of the same color may have different elliptical axis angles (or angles of axis of the elliptical shape). For example, the green sub-pixel Pg may include a first green sub-pixel Pg1 and a second green sub-pixel Pg2 as shown in FIG. 9A. In an embodiment, the first green sub-pixel Pg1 and the second green subpixel Pg2 may have different elliptical axes angles, for example, the angles of the major axes. In the present specification, an elliptical axis angle may denote a rotational angle of an axis with respect to the x axis. For example, a long axis of the first green sub-pixel Pg1 may have an angle of about 45° with respect to the x axis, and a long axis of the second green sub-pixel Pg2 may have an angle of about −45° with respect to the x axis. That is, each of the plurality of sub-pixels may be arranged to have the elliptical shape and an irregular axis angle.

As shown in FIG. 9A, when the plurality of sub-pixels have the elliptical shape, but are arranged to have different axis angles, diffraction caused by reflected light may be reduced. When the plurality of sub-pixels are arranged in a circular shape or in an elliptical shape having the same axis angle, a light spreading phenomenon may occur due to diffraction of reflected light. In contrast, the display device according to an embodiment may firstly reduce the diffraction pattern by arranging the plurality of scattering particles 630s on the upper surface of the color filter layer 630, and secondly more effectively improve diffraction visibility by forming the plurality of sub-pixels to have an elliptical shape with different axial angles.

FIG. 9B illustrates cross-sectional structures of the first green sub-pixel Pg1 and the second green sub-pixel Pg2 of FIG. 8. Referring to FIG. 9B, each of the first green sub-pixel Pg1 and the second green sub-pixel Pg2 may include the first sub-pixel electrode 210G, the first intermediate layer 220G, and the opposite electrode 230 forming the first organic light-emitting diode OLED1. Light reflected from each sub-pixel may be light reflected from a metal layer of each sub-pixel (for example, the sub-pixel electrode or the opposite electrode). For example, a first green light Lg1 may be light reflected from the first sub-pixel electrode 210G of the first green sub-pixel Pg1. A second green light Lg2 may be light reflected from the first sub-pixel electrode 210G of the second green sub-pixel Pg2.

In an embodiment, a vertical distance hg1 from the substrate 100 to the first sub-pixel electrode 210G of the first green sub-pixel Pg1 may be different from a vertical distance hg2 from the substrate 100 to the second sub-pixel electrode 210G of the second green sub-pixel Pg2. For example, the vertical distance hg1 from the substrate 100 to the first sub-pixel electrode 210G of the first green sub-pixel Pg1 may be greater than the vertical distance hg2 from the substrate 100 to the first sub-pixel electrode 210G of the second green sub-pixel Pg2.

In an embodiment, a thickness of the planarization layer 207 corresponding to the first green sub-pixel Pg1 may be different from a thickness of the planarization layer 207 corresponding to the second green sub-pixel Pg2. For example, the thickness of the planarization layer 207 corresponding to the first green sub-pixel Pg1 may be greater than the thickness of the planarization layer 207 corresponding to the second green sub-pixel Pg2.

In other words, the height of the first sub-pixel electrode 210G of the first green sub-pixel Pg1 based on the substrate 100 may be different from the height of the first sub-pixel electrode 210G of the second green sub-pixel Pg2. For example, the height of the first sub-pixel electrode 210G of the first green sub-pixel Pg1 may be greater than the height of the first sub-pixel electrode 210G of the second green sub-pixel Pg2. Accordingly, travel paths of the first green light Lg1 and the second green light Lg2 reflected from the respective first sub-pixel electrodes 210G may be different from each other. For example, a travel path of the first green light Lg1 may be shorter than a travel path of the second green light Lg2.

Because the height of the first sub-pixel electrode 210G of the first green sub-pixel Pg1 based on the substrate 100 is different from the height of the first sub-pixel electrode 210G of the second green sub-pixel Pg2, the thicknesses of the organic encapsulation layer 420 covering the respective first sub-pixel electrodes 210G may be different from each other. Among the travel paths of the first green light Lg1 and the second green light Lg2, the thicknesses of the organic encapsulation layer 420 through which the first green light Lg1 and the second green light Lg2 pass may be different from each other. For example, the thickness dg1 of the organic encapsulation layer 420 corresponding to the first green sub-pixel Pg1 may be less than the thickness dg2 of the organic encapsulation layer 420 corresponding to the second green sub-pixel Pg2.

Accordingly, the first green light Lg1 and the second green light Lg2 may have a phase difference. In an embodiment, the first green light Lg1 and the second green light Lg2 may have a phase difference that does not cause constructive interference or destructive interference with each other. As shown in FIG. 9B, when the plurality of sub-pixels emit light having a phase difference that does not cause constructive interference of destructive interference, a diffraction phenomenon due to reflected light may be reduced. In conclusion, the display device according to an embodiment may firstly, reduce a diffraction pattern by arranging the plurality of scattering particles 630s on the upper surface of a color filter layer 630, secondly, further reduce a diffraction phenomenon by forming the plurality of sub-pixels to have an elliptical shape with different axial angles, and thirdly, effectively improve diffraction visibility by allowing the plurality of sub-pixels to emit light with a phase difference.

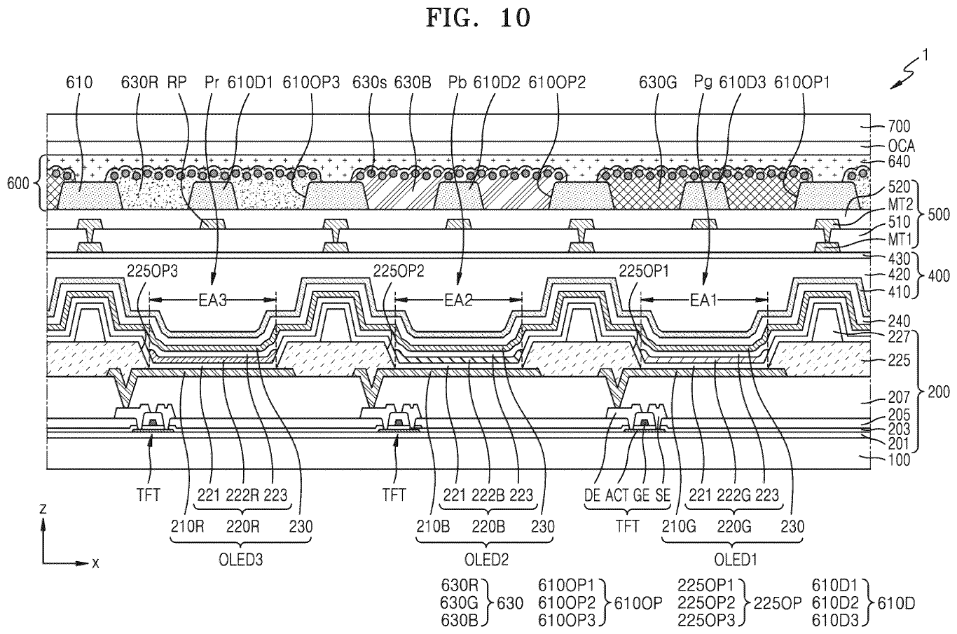

FIG. 10 is a schematic cross-sectional view of a portion of the display device 1 according to an embodiment. Referring to FIG. 10, except for the characteristics of the reflective pattern RP and the light-shielding pattern 610D, other characteristics are the same as those described above with reference to FIGS. 5 and 6. The descriptions regarding the components indicated by the same reference symbols in FIG. 10 are generally the same with those provided above with reference to FIGS. 5 and 6, and the differences therebetween are mainly described hereinafter.

Referring to FIG. 10, the touch sensor layer 500 may include a first touch electrode MT1, a first touch insulating layer 510, a second touch electrode MT2, a second touch insulating layer 520, and a reflective pattern RP. The reflective pattern RP may be disposed on the same layer as the second touch electrode MT2, spaced apart from the second touch electrode MT2, and floated. The reflective pattern RP may be disposed to overlap the emission areas of each of the first to third organic light-emitting diodes OLED1, OLED2, and OLED3. For example, the reflective pattern RP may be disposed to overlap the central portion of the first emission area EA1, the central portion of the second emission area EA2, or the central portion of the third emission area EA3.

The reflective pattern RP is disposed on the same layer as the second touch electrode MT2, and may include the same material as the second touch electrode MT2. For example, the reflective pattern RP may include a metal layer or a transparent conductive layer. The reflective pattern RP may include Ag, an alloy containing Ag, Mo, an alloy containing Mo, Al, an alloy containing Al, AlN, tungsten (W), tungsten nitride (WN), Cu, Ni, Cr, chromium nitride (CrN), Ti, Ta, Pt, scandium (Sc), ITO, IZO, or the like.

As the reflective pattern RP including the aforementioned material is arranged to overlap the emission area, the reflective pattern RP may reflect light emitted from the light-emitting diode. In addition, the light reflected from the reflective pattern RP may be reflected again from a structure (e.g., a sub-pixel electrode) located under the reflective pattern RP and then may be emitted to the outside. Accordingly, the recycling efficiency of light emitted from the light-emitting diode may be enhanced.

The optical control layer 600 may be disposed on the touch sensor layer 500. The optical control layer 600 may include a light-shielding layer 610, a light-shielding pattern 610D, a color filter layer 630, and an overcoat layer 640. The light-shielding pattern 610D may be disposed in the upper opening 610OP of the light-shielding layer 610, and may be spaced apart from the light-shielding layer 610. A plurality of light-shielding patterns 610D may be provided and may be spaced apart from each other to correspond to the sub-pixels, respectively. For example, the light-shielding patterns 610D may include a first light-shielding pattern 610D1 corresponding to the green sub-pixel Pg, a second light-shielding pattern 610D2 corresponding to the blue sub-pixel Pb, and a third light-shielding pattern 610D3 corresponding to the red sub-pixel Pr.

As the light-shielding pattern 610D is disposed in the upper opening 610OP, the light-shielding pattern 610D may be arranged to overlap the emission area and the lower opening 225OP. In addition, the light-shielding pattern 610D may be arranged to correspond to the reflective pattern RP. Specifically, the light-shielding pattern 610D may be arranged on the reflective pattern RP to overlap the same in a plan view.

The light-shielding pattern 610D may include the same material as the light-shielding layer 610. In other words, the light-shielding pattern 610D may include an organic insulating material or an inorganic insulating material and may further include a light-shielding material. For example, the light-shielding material of the light-shielding pattern 610D may be black. The light-shielding material may include carbon black, carbon nanotubes, resin or paste including a black dye, metal particles such as Ni, Al, Mo, and an alloy thereof, metal oxide particles, metal nitride particles, or the like. Similar to the light-shielding layer 610, the light-shielding pattern 610D may include a light-shielding material and thus may reduce the external light reflection from the metal structures arranged under the light-shielding pattern 610D.

That is, when the display device 1 includes the reflective pattern RP and the light-shielding pattern 610D as shown in FIG. 10, it is possible to reduce reflection of external light while increasing the recycling efficiency of light. Accordingly, the display device 1 according to an embodiment may firstly reduce the diffraction pattern by arranging the plurality of scattering particles 630s on the upper surface of the color filter layer 630, and secondly, more effectively improve the diffraction visibility by arranging the reflective pattern RP and the light-shielding pattern 610D.

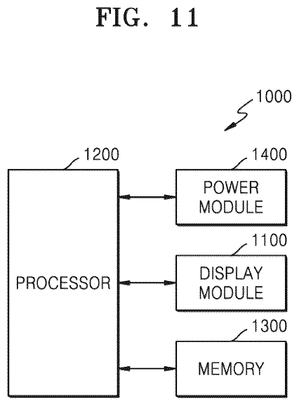

FIG. 11 is a block diagram of an electronic device according to an embodiment.

Referring to FIG. 11, an electronic device 1000 according to an embodiment may include a display module 1100, a processor 1200, a memory 1300, a power module 1400.

The electronic device 1000 may use the display module 1100 to output various types of information under an operating system.

The processor 1200 may include at least one of a Central Processing Unit (CPU), an Application Processor (AP), a Graphics Processing Unit (GPU), a Communication Processor (CP), an Image Signal Processor (ISP), and a controller. In an embodiment, the processor 1200 may be divided into at least two processors from a functional or structural perspective. For example, the processor 1200 may include a main processor in the form of a first driving chip, which includes a CPU, and an auxiliary processor in the form of a second driving chip, which includes a controller that receives an image signal from the main processor and processes the same to conform to the interface specifications of the display module 1100. The processor may include one or more processors. The one or more processors may operate individually, as a collective or as a subset of the collective. For example, two out of three processors may operate together to execute an application.

The memory 1300 may include at least one of non-volatile memory and volatile memory. Data information for the operation of the processor 1200 or the display module 1100 may be stored in the memory 1300. When the processor 1200 executes an application stored in the memory 1300, an image data signal and/or an input control signal may be transmitted to the display module 1100, and the display module 1100 may process such signals to output image information through a display screen.

The power module 1400 may include a power supply module, such as a power adaptor or a battery device, and a power conversion module that generates power for the operation of the electronic device 1000 by converting the power supplied by the power supply module. The power conversion by the power conversion module may include DC-DC conversion, AC-DC conversion, and DC-AC conversion, but is not limited thereto.

At least one of the components of the electronic device 1000 described above may be included in the display device according to the one or more embodiments. In addition, some of individual modules functionally included in a single module may be included in the display device, and others thereof may be provided separately from the display device. For example, the display device may include the display module 1100 and the auxiliary processor of the processor 1200, and the main processor of the processor 1200, the memory 1300, and the power module 1400 may be provided as separate devices in the electronic device 1000, rather than in the display device. As an example, the power module 1400 may be included in the display device and supply power to the processor 1200 and the memory 1300 provided in the electronic device 1000, rather than in the display device, however, one or more embodiments are not limited thereto.

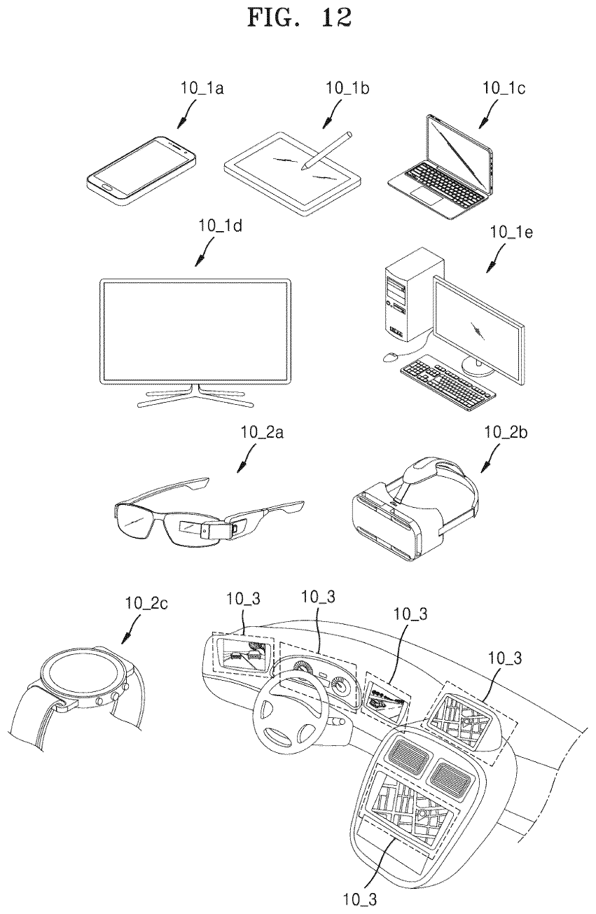

FIG. 12 is a schematic diagram of electronic devices according to various embodiments.

The display device according to one or more embodiments may display a moving image or a still image and is applicable to various electronic devices. Referring to FIG. 12, examples of various electronic devices to which the display device according to embodiments is applied may include electronic devices for image display, such as a smartphone 10_1a, a tablet personal computer (PC) 10_1b, a laptop 10_1c, a television (TV) 10_1d, or a desktop monitor 10_1e; wearable electronic devices including a display module, such as smart glasses 10_2a, a head-mounted display 10_2b, or a smart watch 10_2c; and vehicle electronic devices 10_3 with a display module, such as an instrument cluster of a vehicle, center fascia, a Center Information Display (CID) on the dashboard, or a room mirror display. The electronic device 1000 according to embodiments is not limited to the devices stated above.

The electronic device of FIG. 12 may include the components shown in FIG. 11. For example, the smartphone 10_1a may include the display module 1100, the processor 1200, the memory 1300, and the power module 1400 shown in FIG. 10. The smartphone 10_1a may further include a communication module and a battery device. The power supplied by the battery device may be converted through the power module 1400 and provided to the processor 1200, the memory 1300, and the display module 1100. In an embodiment, the display device applied to the smartphone 10_1a may include the display module 1100 and further include the power module 1400. The processor 1200 and the memory 1300 may each be provided in the form of chips mounted on a motherboard that is an external device, but one or more embodiments are not limited thereto.

One or more embodiments may provide a display device with improved display quality, an electronic device including the display device, and a method of manufacturing a display device. The above effect is merely an example, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a display layer disposed on the substrate and comprising a first light-emitting diode and a bank layer that includes a first lower opening defining an emission area of the first light-emitting diode; and
an optical control layer disposed on the display layer and the optical control layer comprising a light-shielding layer that includes a first upper opening and a first color filter, the first upper opening at least partially aligned with the first lower opening and the first color filter filling the first upper opening,
wherein the first color filter passes light of a first color among light emitted from the first light-emitting diode,
the first color filter comprises a plurality of first scattering particles and a base resin, and
the plurality of first scattering particles are disposed in an upper area of the first color filter.

2. The display device of claim 1, wherein
an upper surface of the first color filter includes a plurality of convex portions protruding by the plurality of first scattering particles.

3. The display device of claim 2, wherein
the first color filter has a non-uniformly curved upper surface.

4. The display device of claim 1, wherein
the plurality of first scattering particles are surface-treated to be hydrophobic or liquid repellent.

5. The display device of claim 1, wherein
the plurality of first scattering particles include silica particles.

6. The display device of claim 1, wherein
a content ratio of the plurality of first scattering particles in the first color filter is about 0.01% to about 5%.

7. The display device of claim 1, wherein
a radius of each of the plurality of first scattering particles is about 50 nm to about 200 nm.

8. The display device of claim 1, wherein
the display layer further comprises a second light-emitting diode and a third light-emitting diode, wherein the second light emitting diode and the third light-emitting diode are spaced apart from the first light-emitting diode,
the bank layer further comprises a second lower opening defining an emission area of the second light-emitting diode and a third lower opening defining an emission area of the third light-emitting diode,
the light-shielding layer further comprises a second upper opening at least partially aligned with the second lower opening and a third upper opening at least partially aligned with the third lower opening, and
the optical control layer further comprises a second color filter filling the second upper opening and a third color filter filling the third upper opening,
wherein the second color filter passes light of a second color among light emitted from the second light-emitting diode, and
the third color filter passes light of a third color among light emitted from the third light-emitting diode.

9. The display device of claim 8, wherein
the second color filter includes a plurality of second scattering particles, the third color filter includes a plurality of third scattering particles, and
at least one plurality of scattering particles selected from the plurality of first scattering particles, the plurality of second scattering particles, and the plurality of third scattering particles, has a diameter different from diameters of others.

10. The display device of claim 1, wherein
the display layer further comprises a fourth light-emitting diode spaced apart from the first light-emitting diode,
the bank layer further comprises a fourth lower opening defining an emission area of the fourth light-emitting diode,
the light-shielding layer further comprises a fourth upper opening at least partially aligned the fourth lower opening, and
the optical control layer further comprises a fourth color filter filling the fourth upper opening,
wherein the fourth color filter and the first color filter include a same material.

11. The display device of claim 10, wherein
each of the first upper opening and the fourth upper opening has an elliptical shape in a plan view, and
an angle of an axis of the elliptical shape of the first upper opening is different from an angle of an axis of the elliptical shape of the fourth upper opening.

12. The display device of claim 10, wherein
a vertical distance between the substrate and a pixel electrode of the first light-emitting diode is different from a vertical distance between the substrate and a pixel electrode of the fourth light-emitting diode.

13. The display device of claim 1, further comprising
a touch sensor layer disposed between the display layer and the optical control layer and comprising a touch electrode and a touch insulating layer covering the touch electrode,
wherein the touch sensor layer further comprises a reflective pattern disposed on a same layer as the touch electrode and overlapping the emission area,
the optical control layer further comprises a light-shielding pattern disposed on a same layer as the light-shielding layer and disposed in the first upper opening, and
the light-shielding pattern is arranged to overlap the reflective pattern in a plan view.

14. A method of manufacturing a display device, the method comprising:
forming, on a substrate, a display layer comprising a light-emitting diode and a bank layer that comprises a lower opening defining an emission area of the light-emitting diode;
forming, on the display layer, a light-shielding layer comprising an upper opening at least partially aligned the lower opening;
forming, within the upper opening, a preliminary color filter layer comprising a color filter material, a plurality of scattering particles, and a base resin; and
forming a color filter layer through a pre-baking process of heating the preliminary color filter layer.

15. The method of claim 14, wherein, in the pre-baking process,
the plurality of scattering particles dispersed in the preliminary color filter layer move to an upper portion of the color filter layer.

16. The method of claim 15, wherein
an upper surface of the color filter layer comprises a plurality of convex portions protruding by the plurality of scattering particles.

17. The method of claim 14, wherein
the forming of the preliminary color filter layer comprises
forming the plurality of scattering particles by performing hydrophobic surface-treatment on silica particles.

18. An electronic device comprising:
a display device configured to provide an image; and
a housing accommodating the display device,
wherein the display device comprises:
a substrate;
a display layer disposed on the substrate and comprising a light-emitting diode and a bank layer that comprises a lower opening defining an emission area of the light-emitting diode; and
an optical control layer disposed on the display layer and comprising a light-shielding layer and a color filter, the light-shielding layer comprising an upper opening at least partially aligned with the lower opening and the color filter filling the upper opening;
wherein the color filter comprises a color filter material, a plurality of scattering particles, and a base resin, and
the plurality of scattering particles are disposed in an upper area of the color filter.

19. The electronic device of claim 18, wherein
an upper surface of the color filter comprises a plurality of convex portions protruding by the plurality of scattering particles.

20. The electronic device of claim 18, wherein
the plurality of scattering particles comprise hydrophobic surface-treated silica particles.
